(19) United States
(12) Patent Application Publication
(10) Pub. No.: US 2026/0142648 A1
(43) Pub. Date: May 21, 2026

(54) ENHANCING SPURIOUS REJECTION IN AN ACOUSTIC FILTER CIRCUIT

(71) Applicant: Qorvo US, Inc., Greensboro, NC (US)

(72) Inventors: Loizos Loizou, Grasbrunn (DE); Valeria Nocella, Munich (DE)

(21) Appl. No.: 19/369,473

(22) Filed: Oct. 27, 2025

Related U.S. Application Data
(60) Provisional application No. 63/722,663, filed on Nov. 20, 2024.

(51) Int. Cl. H03H 9/60

(52) U.S. Cl. CPC H03H 9/605

(57) ABSTRACT

Enhancing spurious rejection in an acoustic filter circuit is provided. Specifically, the filter circuit includes an acoustic bandpass filter circuit and an acoustic bandstop filter circuit. In embodiments disclosed herein, the acoustic bandpass filter circuit and the acoustic bandstop filter circuit can be integrated into either a single semiconductor die or a single system-in-package (SiP). By integrating the acoustic bandstop filter circuit with the acoustic bandpass filter circuit, it is possible to enhance spurious rejection with minimum impact on insertion loss and passband performance to thereby improve overall performance of the acoustic filter circuit. Moreover, it is possible to reduce fabrication variation and cost of the acoustic filter circuit as well.

### RELATED APPLICATIONS

This application claims the benefit of U.S. provisional patent application serial number 63/722,663, filed on November 20, 2024, the disclosure of which is incorporated herein by reference in its entirety.

### FIELD OF THE DISCLOSURE

The technology of the disclosure relates generally to improving spurious rejection in an acoustic filter in a wireless communication device.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as Surface Acoustic Wave (SAW) resonators and Bulk Acoustic Wave (BAW) resonators, are used in many high-frequency communication applications. In particular, SAW resonators are often employed in filter networks that operate at frequencies up to 1.8 GHz, and BAW resonators are often employed in filter networks that operate at frequencies above 1.5 GHz. Such SAW and BAW-based filters have flat passbands, steep filter skirts, and squared shoulders at the upper and lower ends of the passbands, and provide excellent rejection outside of the passbands. SAW and BAW-based filters also have a relatively low insertion loss, tend to decrease in size as the frequency of operation increases, and are relatively stable over wide temperature ranges.

As such, SAW and BAW-based filters are the filters of choice for many wireless devices. Most of these wireless devices support cellular, wireless fidelity (Wi-Fi), Bluetooth, and/or near field communications on the same wireless device and, as such, pose extremely challenging filtering demands. While these demands keep raising the complexity of wireless devices, there is a constant need to improve the performance of acoustic resonators and filters that are based thereon.

### SUMMARY

Aspects disclosed in the detailed description include enhancing spurious rejection in an acoustic filter circuit. Specifically, the acoustic filter circuit includes an acoustic bandpass filter circuit and an acoustic bandstop filter circuit. In embodiments disclosed herein, the acoustic bandpass filter circuit and the acoustic bandstop filter circuit can be integrated into either a single semiconductor die or a single system-in-package (SiP). By integrating the acoustic bandstop filter circuit with the acoustic bandpass filter circuit, it is possible to enhance spurious rejection with minimum impact on insertion loss and passband performance to thereby improve overall performance of the acoustic filter circuit. Moreover, it is possible to reduce fabrication variation and cost of the acoustic filter circuit as well.

In one aspect, an integrated acoustic bandpass-bandstop filter circuit is provided. The integrated acoustic bandpass-bandstop filter circuit includes an acoustic bandpass filter circuit. The acoustic bandpass filter circuit is configured to resonate in one or more acoustic resonance frequencies to thereby pass a signal in a passband including the one or more acoustic resonance frequencies. The integrated acoustic bandpass-bandstop filter circuit also includes an acoustic bandstop filter circuit. The acoustic bandstop filter circuit is coupled in series to the acoustic bandpass filter circuit. The acoustic bandstop filter circuit is configured to block the signal in a stopband nonoverlapping with the passband.

In another aspect, a wireless device is provided. The wireless device includes an integrated acoustic bandpass-bandstop filter circuit. The integrated

acoustic bandpass-bandstop filter circuit includes an acoustic bandpass filter circuit. The acoustic bandpass filter circuit is configured to resonate in one or more acoustic resonance frequencies to thereby pass a signal in a passband including the one or more acoustic resonance frequencies. The integrated acoustic bandpass-bandstop filter circuit also includes an acoustic bandstop filter circuit. The acoustic bandstop filter circuit is coupled in series to the acoustic bandpass filter circuit. The acoustic bandstop filter circuit is configured to block the signal in a stopband nonoverlapping with the passband.

In another aspect, a method for making an integrated acoustic bandpass-bandstop filter circuit is provided. The method includes integrating an acoustic bandpass filter circuit and an acoustic bandstop filter circuit into one of a single semiconductor die and a single SiP. The method also includes configuring the acoustic bandpass filter circuit to resonate in one or more acoustic resonance frequencies to thereby pass a signal in a passband including the one or more acoustic resonance frequencies. The method also includes coupling the acoustic bandstop filter circuit in series to the acoustic bandpass filter circuit to block the signal in a stopband nonoverlapping with the passband.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary integrated acoustic bandpass-bandstop filter circuit configured according to an embodiment of the present disclosure to integrate an acoustic bandpass filter circuit and an acoustic bandstop filter circuit into a single semiconductor die or a single system-in-package (SiP);

FIG. 2 is a schematic diagram of the acoustic bandpass filter circuit in FIG. 1;

FIGS. 3A-3C are schematic diagrams illustrating the acoustic bandstop filter circuit in FIG. 1;

FIGS. 4A and 4B are graphic diagrams illustrating a performance comparison between the integrated acoustic bandpass-bandstop filter circuit of FIG. 1 and a passband-only solution;

FIG. 5 is a schematic diagram of an exemplary integrated acoustic bandpass-bandstop filter circuit configured according to another embodiment of the present disclosure;

FIG. 6 is a schematic diagram of an exemplary communication device wherein the integrated acoustic multiplexer filter circuit of FIGS. 1 and 5 can be provided; and

FIG. 7 is a flowchart of an exemplary process for making the integrated acoustic bandpass-bandstop filter circuit of FIGS. 1 and 5.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include enhancing spurious rejection in an acoustic filter circuit. Specifically, the acoustic filter circuit includes an acoustic bandpass filter circuit and an acoustic bandstop filter circuit. In embodiments disclosed herein, the acoustic bandpass filter circuit and the acoustic bandstop filter circuit can be integrated into either a single semiconductor die or a single system-in-package (SiP). By integrating the acoustic bandstop filter circuit with the acoustic bandpass filter circuit, it is possible to enhance spurious rejection with minimum impact on insertion loss and passband performance to thereby improve overall performance of the acoustic filter circuit. Moreover, it is possible to reduce fabrication variation and cost of the acoustic filter circuit as well.

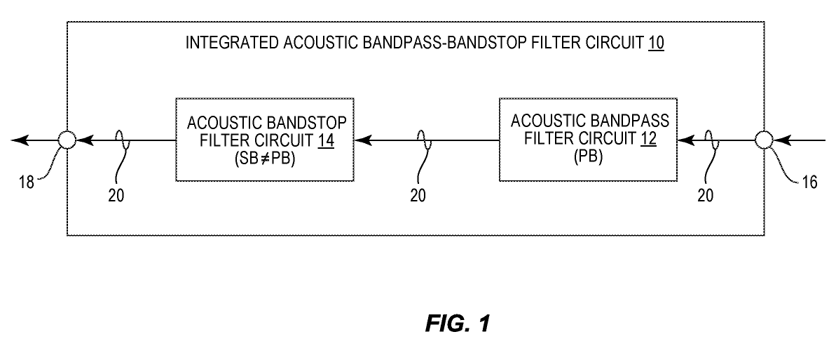

FIG. 1 is a schematic diagram of an exemplary integrated acoustic bandpass-bandstop filter circuit 10 (a.k.a. “acoustic filter circuit”) configured according to an embodiment of the present disclosure to integrate an acoustic bandpass filter circuit 12 and an acoustic bandstop filter circuit 14 into a single semiconductor die or a single SiP. Herein, the acoustic bandpass filter circuit 12 and the acoustic bandstop filter circuit 14 are coupled in series between an input port 16 and an output port 18. Specifically, the acoustic bandpass filter circuit 12 is coupled to the input port 16 and the acoustic bandstop filter circuit 14 is coupled between the acoustic bandpass filter circuit 12 and the output port 18.

The acoustic bandpass filter circuit 12 is configured to pass a signal 20 in a passband PB. The acoustic bandstop filter circuit 14, on the other hand, is configured to also pass the signal 20 in the passband PB but block unwanted frequency components (e.g., harmonics) in a stopband SB that does not overlap with the passband PB. As a result, the signal 20 can be passed from the input port 16 to the output port 18 with reduced frequency distortion, thus helping to improve overall performance of the integrated acoustic bandpass-bandstop filter circuit 10.

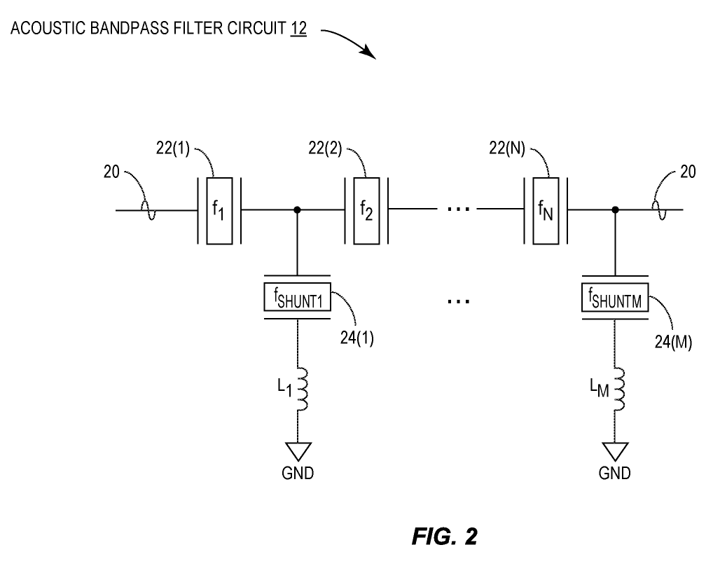

In an embodiment, the acoustic bandpass filter circuit 12 can be configured as an acoustic bandpass ladder network. In this regard, FIG. 2 is a schematic diagram of the acoustic bandpass filter circuit 12 in FIG. 1. Common elements between FIGS. 1 and 2 are shown therein with common element numbers and will not be re-described herein.

Herein, the acoustic bandpass filter circuit 12 includes one or more series acoustic resonators 22(1)-22(N) and one or more acoustic shunt resonators 24(1)-24(M). Each of the series acoustic resonators 22(1)-22(N) is configured to resonate at a respective one of one or more series resonance frequencies f₁-f_{N} to thereby pass the signal 20 in the passband PB. Notably, the series resonance frequencies f₁-f_{N} are not necessarily identical. Nevertheless, the series resonance frequencies f₁-f_{N} must be at least partially overlapping or close enough to collectively define the passband PB. In this regard, the passband PB will include all of the series resonance frequencies f₁-f_{N}.

Each of the acoustic shunt resonators 24(1)-24(M) is coupled to a ground (GND) via a respective one of one or more shunt inductors L₁-L_{M}. The acoustic shunt resonators 24(1)-24(M) are each configured to pass the signal 20 but shunt unwanted frequency components in the passband PB to the GND in a respective one of one or more shunt frequencies f_{SHUNT1}-F_{SHUNTM}. Notably, the shunt frequencies f_{SHUNT1}-F_{SHUNTM} are not necessarily identical. Nevertheless, the shunt frequencies f_{SHUNT1}-F_{SHUNTM} should not overlap with any of the series resonance frequencies f₁-f_{N}. In this regard, the passband PB will further include all of the shunt frequencies f_{SHUNT1}-F_{SHUNTM}.

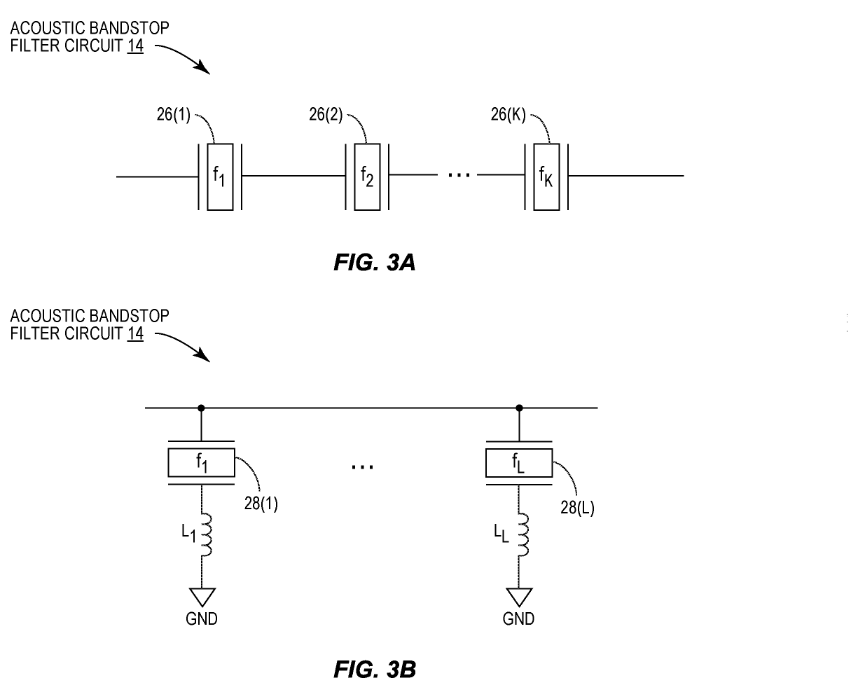

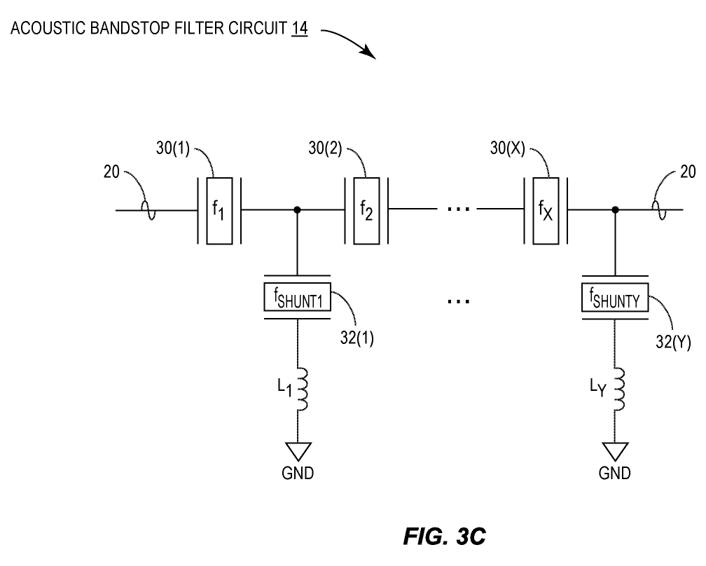

With reference back to FIG. 1, the acoustic bandstop filter circuit 14 may be configured according to various embodiments of the present disclosure, as describe next in FIGS. 3A-3C. Common elements between FIGS. 1 and 3A-3C are shown therein with common element numbers and will not be re-described herein.

FIG. 3A is a schematic diagram illustrating the acoustic bandstop filter circuit 14 in FIG. 1 configured according to one embodiment of the present disclosure. Herein, the acoustic bandstop filter circuit 14 includes one or more acoustic resonators 26(1)-26(K) coupled in series. Each of the acoustic resonators 26(1)-26(K) has a respective one of one of more resonance frequencies f₁-f_{K} so determined to pass the signal 20 in the passband PB and block the unwanted frequency components in the stopband SB. Notably, the resonance frequencies f₁-f_{K} are not necessarily identical. Nevertheless, the resonance frequencies f₁-f_{K} should collectively define at least a portion of the stopband SB.

FIG. 3B is a schematic diagram illustrating the acoustic bandstop filter circuit 14 in FIG. 1 configured according to another embodiment of the present disclosure. Herein, the acoustic bandstop filter circuit 14 includes one or more acoustic resonators 28(1)-28(L) coupled in parallel. Specifically, each of the acoustic resonators 28(1)-28(L) is coupled to the GND either directly or via a respective one of one or more shunt inductors L₁-L_{L}. Each of the acoustic resonators 28(1)-28(L) has a respective one of one of more resonance frequencies f₁-f_{L} so determined to shunt the unwanted frequency components in the stopband SB to the GND. Notably, the resonance frequencies f₁-f_{L} are not necessarily identical. Nevertheless, the resonance frequencies f₁-f_{L} should collectively define the stopband SB.

FIG. 3C is a schematic diagram illustrating the acoustic bandstop filter circuit 14 in FIG. 1 configured according to another embodiment of the present disclosure. Herein, the acoustic bandstop filter circuit 14 is implemented by an acoustic bandstop ladder network.

Specifically, the acoustic bandstop filter circuit 14 includes one or more series acoustic resonators 30(1)-30(X) and one or more acoustic shunt resonators 32(1)-32(Y). Each of the series acoustic resonators 30(1)-30(X) is configured to resonate at a respective one of one or more series resonance frequencies f₁-f_{X} to thereby pass the signal 20 with minimum attenuation in the passband PB, as well as rejecting undesired spectrum, in the stopband SB. Notably, the series resonance frequencies f₁-f_{X} are not necessarily identical. Nevertheless, the series resonance frequencies f₁-f_{X} must at least be partially overlapping or close enough to pass the signal 20 with minimum attenuation in at least part of the passband PB.

Each of the acoustic shunt resonators 32(1)-32(Y) is coupled either directly to the GND or via a respective one of one or more shunt inductors L₁-L_{Y}. The acoustic shunt resonators 32(1)-32(Y) are each configured to shunt the unwanted frequency components to the GND in a respective one of one or more shunt frequencies f_{SHUNT1}-F_{SHUNTY,} which are part of the stopband SB. In this regard, the stopband SB can be defined by a combination of the series resonance frequencies f₁-f_{X} and the shunt frequencies f_{SHUNT1}-F_{SHUNTY}.

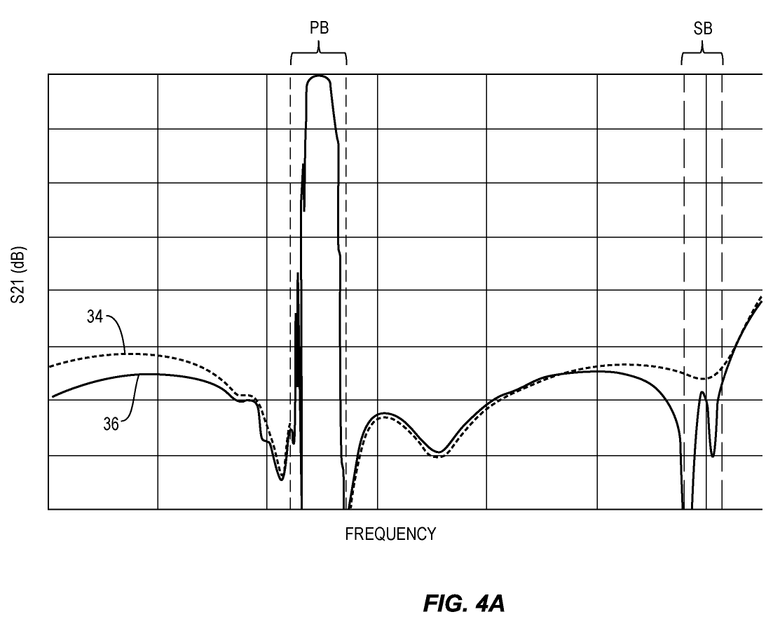

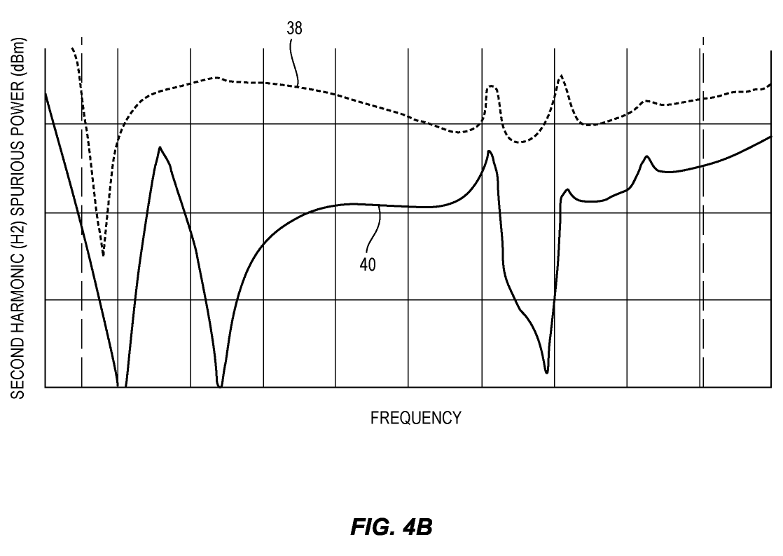

Compared to a passband-only solution wherein only the acoustic bandpass filter circuit 12 is included, the integrated acoustic bandpass-bandstop filter circuit 10 of FIG. 1 can reject more unwanted frequency components in the stopband SB. FIGS. 4A and 4B are graphic diagrams illustrating a performance comparison between the integrated acoustic bandpass-bandstop filter circuit 10 of FIG. 1 and a passband-only solution.

FIG. 4A is a graphic diagram illustrating one aspect of the performance comparison between the integrated acoustic bandpass-bandstop filter circuit 10 and the passband-only solution. Herein, the frequency rejection or transmission performance of the passband-only solution is illustrated by a first curve 34, whereas the frequency rejection performance of the integrated acoustic bandpass-bandstop filter circuit 10 is illustrated by a second curve 36. Notably, the integrated acoustic bandpass-bandstop filter circuit 10 can achieve a similar performance in the passband PB as the passband-only solution but introduces extra rejection in the stopband SB.

FIG. 4B is a graphic diagram illustrating another aspect of the performance comparison between the integrated acoustic bandpass-bandstop filter circuit 10 and the passband-only solution. Herein, a second harmonic (H2) floor of the passband-only solution is illustrated by a first curve 38, whereas the H2 floor of the integrated acoustic bandpass-bandstop filter circuit 10 is illustrated by a second curve 40. Notably, the integrated acoustic bandpass-bandstop filter circuit 10 can achieve a lower H2 floor compared to the passband-only solution, thus proving that the integrated acoustic bandpass-bandstop filter circuit 10 can enhance spurious rejection over the passband-only solution.

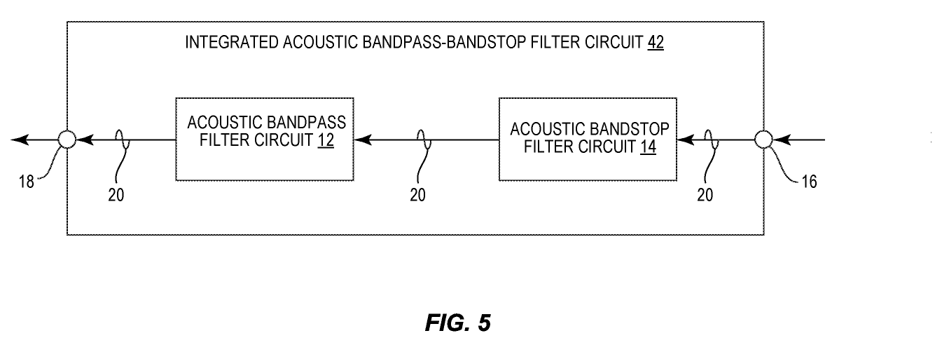

The integrated acoustic bandpass-bandstop filter circuit 10 of FIG. 1 may also be configured according to an alternative topology. In this regard, FIG. 5 is a schematic diagram of an exemplary integrated acoustic bandpass-bandstop filter circuit 42 configured according to another embodiment of the present disclosure. Common elements between FIGS. 1 and 5 are shown therein with common element numbers and will not be re-described herein.

Herein, the acoustic bandstop filter circuit 14 is coupled to the input port 16, whereas the acoustic bandpass filter circuit 12 is coupled between the acoustic bandstop filter circuit 14 and the output port 18. Notably, the acoustic bandpass filter circuit 12 can be implemented as illustrated in FIG. 2, whereas the acoustic bandstop filter circuit 14 may be implemented according to any embodiment as illustrated in FIGS. 3A-3C.

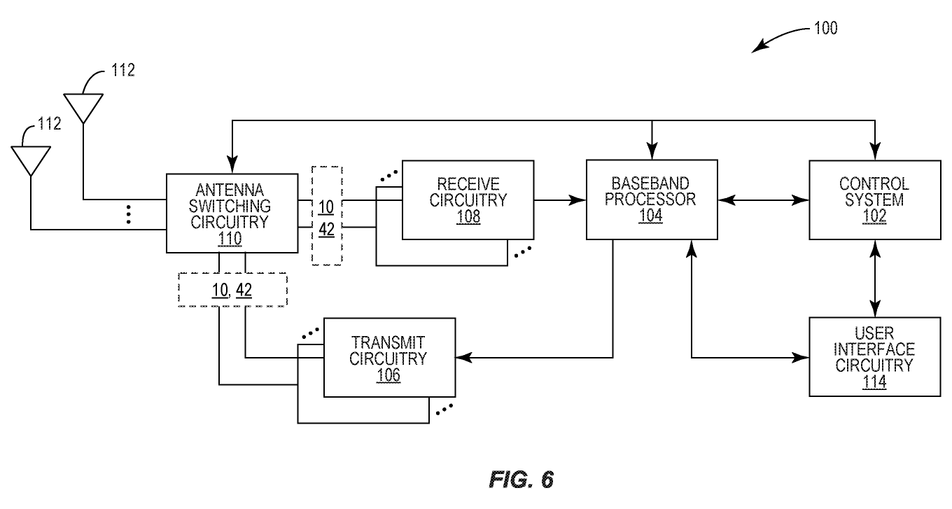

The integrated acoustic bandpass-bandstop filter circuit 10 of FIG. 1 and the integrated acoustic bandpass-bandstop filter circuit 42 of FIG. 5 can be provided in a communication device to support the embodiments described above. In this regard, FIG. 6 is a schematic diagram of an exemplary communication device 100 wherein the integrated acoustic bandpass-bandstop filter circuit 10 of FIG. 1 and the integrated acoustic bandpass-bandstop filter circuit 42 of FIG. 5 can be provided.

Herein, the communication device 100 can be any type of communication devices, such as mobile terminals, smart watches, tablets, computers, navigation devices, access points, and like wireless communication devices that support wireless communications, such as cellular, wireless local area network (WLAN), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the integrated acoustic bandpass-bandstop filter circuit 10 or the integrated acoustic bandpass-bandstop filter circuit 42 may be provided between the transmit circuitry 106 and the antenna switching circuitry 110 and/or between the receive circuitry 108 and the antenna switching circuitry 110. Understandably, the integrated acoustic bandpass-bandstop filter circuit 10 or the integrated acoustic bandpass-bandstop filter circuit 42 may also be provided in any other circuitries in the communication device 100.

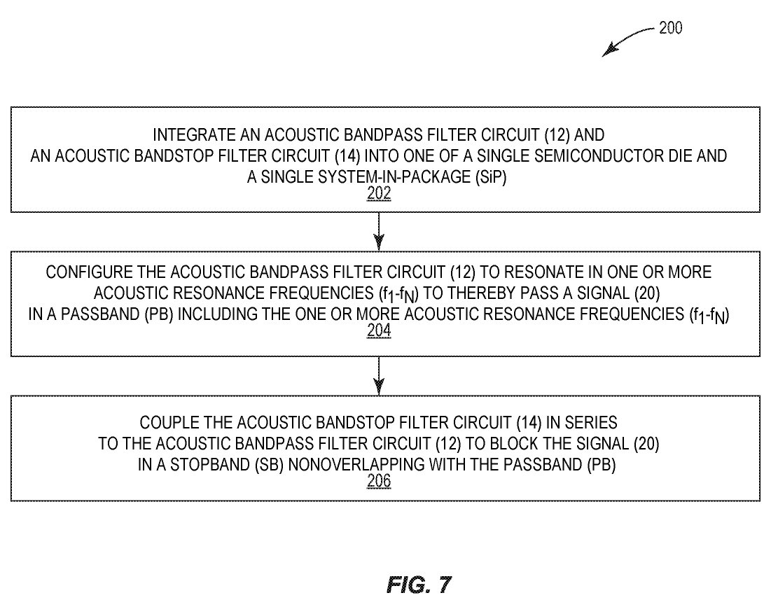

The integrated acoustic bandpass-bandstop filter circuit 10 of FIG. 1 can be made based on a process. In this regard, FIG. 7 is a flowchart of an exemplary process 200 for making the integrated acoustic bandpass-bandstop filter circuit 10 of FIG. 1.

Herein, the process 200 includes integrating the acoustic bandpass filter circuit 12 and the acoustic bandstop filter circuit 14 into one of a single semiconductor die and a single SiP (step 202). The process 200 also includes configuring the acoustic bandpass filter circuit 12 to resonate in one or more of the acoustic resonance frequencies f₁-f_{N} to thereby pass the signal 20 in the passband PB including the one or more of the acoustic resonance frequencies f₁-f_{N} (step 204). The process 200 also includes coupling the acoustic bandstop filter circuit 14 in series to the acoustic bandpass filter circuit 12 to block the signal 20 in the stopband SB nonoverlapping with the passband PB (step 206). As an example, the signal 20 can include a wanted portion and an unwanted portion that do not overlap with one another. Herein, the acoustic bandstop filter circuit 14 is coupled in series to the acoustic bandpass filter circuit 12 to pass the wanted portion of the signal 20 with minimum attenuation and block the unwanted portion of the signal 20. In some applications, the acoustic bandpass filter circuit 12 may also introduce the unwanted portion (e.g., harmonics), which can be eliminated by the acoustic bandstop filter circuit 14.

Those skilled in the art will recognize improvements and modifications to the embodiments of the present disclosure. All such improvements and modifications are considered within the scope of the concepts disclosed herein and the claims that follow.

What is claimed is:

1. An integrated acoustic bandpass-bandstop filter circuit comprising:
an acoustic bandpass filter circuit configured to resonate in one or more acoustic resonance frequencies to thereby pass a signal in a passband comprising the one or more acoustic resonance frequencies; and
an acoustic bandstop filter circuit coupled in series to the acoustic bandpass filter circuit and configured to block the signal in a stopband nonoverlapping with the passband.

2. The integrated acoustic bandpass-bandstop filter circuit of claim 1, wherein the acoustic bandpass filter circuit and the acoustic bandstop filter circuit are integrated into a single semiconductor die.

3. The integrated acoustic bandpass-bandstop filter circuit of claim 1, wherein the acoustic bandpass filter circuit and the acoustic bandstop filter circuit are integrated into a single system-in-package (SiP).

4. The integrated acoustic bandpass-bandstop filter circuit of claim 1, further comprising an input port and an output port, wherein:
the acoustic bandpass filter circuit is coupled to the input port; and
the acoustic bandstop filter circuit is coupled between the acoustic bandpass filter circuit and the output port.

5. The integrated acoustic bandpass-bandstop filter circuit of claim 1, further comprising an input port and an output port, wherein:
the acoustic bandstop filter circuit is coupled to the input port; and
the acoustic bandpass filter circuit is coupled between the acoustic bandstop filter circuit and the output port.

6. The integrated acoustic bandpass-bandstop filter circuit of claim 1, wherein the acoustic bandpass filter circuit comprises an acoustic bandpass ladder network configured to pass the signal in one or more series resonance frequencies that collectively define the passband.

7. The integrated acoustic bandpass-bandstop filter circuit of claim 1, wherein the acoustic bandstop filter circuit comprises one or more acoustic resonators coupled in series and configured to pass the signal in one or more resonance frequencies that collectively define at least a portion of the stopband.

8. The integrated acoustic bandpass-bandstop filter circuit of claim 1, wherein the acoustic bandstop filter circuit comprises one or more acoustic shunt resonators coupled in parallel and configured to block the signal in one or more resonance frequencies that collectively define the stopband.

9. The integrated acoustic bandpass-bandstop filter circuit of claim 1, wherein the acoustic bandstop filter circuit comprises an acoustic bandstop ladder network configured to pass the signal in one or more series resonance frequencies that are part of the passband and block the signal in one or more shunt frequencies that are part of the stopband.

10. A wireless device comprising an integrated acoustic bandpass-bandstop filter circuit, the integrated acoustic bandpass-bandstop filter circuit comprises:
an acoustic bandpass filter circuit configured to resonate in one or more acoustic resonance frequencies to thereby pass a signal in a passband comprising the one or more acoustic resonance frequencies; and
an acoustic bandstop filter circuit coupled in series to the acoustic bandpass filter circuit and configured to block the signal in a stopband nonoverlapping with the passband.

11. The wireless device of claim 10, wherein the acoustic bandpass filter circuit and the acoustic bandstop filter circuit are integrated into a single semiconductor die.

12. The wireless device of claim 10, wherein the acoustic bandpass filter circuit and the acoustic bandstop filter circuit are integrated into a single system-in-package (SiP).

13. The wireless device of claim 10, wherein the acoustic bandpass filter circuit is coupled to an input port and the acoustic bandstop filter circuit is coupled between the acoustic bandpass filter circuit and an output port.

14. The wireless device of claim 10, wherein the acoustic bandstop filter circuit is coupled to an input port and the acoustic bandpass filter circuit is coupled between the acoustic bandstop filter circuit and an output port.

15. The wireless device of claim 10, wherein the acoustic bandpass filter circuit comprises an acoustic bandpass ladder network configured to pass the signal in one or more series resonance frequencies that collectively define the passband.

16. The wireless device of claim 10, wherein the acoustic bandstop filter circuit comprises one or more acoustic resonators coupled in series and configured to pass the signal in one or more resonance frequencies that collectively define at least a portion of the passband.

17. The wireless device of claim 10, wherein the acoustic bandstop filter circuit comprises one or more acoustic shunt resonators coupled in parallel and configured to block the signal in one or more resonance frequencies that collectively define the stopband.

18. The wireless device of claim 10, wherein the acoustic bandstop filter circuit comprises an acoustic bandstop ladder network configured to pass the signal in one or more series resonance frequencies that are part of the passband and block the signal in one or more shunt frequencies that are part of the stopband.

19. A method for making an integrated acoustic bandpass-bandstop filter circuit comprising:
integrating an acoustic bandpass filter circuit and an acoustic bandstop filter circuit into one of a single semiconductor die and a single system-in-package (SiP);
configuring the acoustic bandpass filter circuit to resonate in one or more acoustic resonance frequencies to thereby pass a signal in a passband comprising the one or more acoustic resonance frequencies; and
coupling the acoustic bandstop filter circuit in series to the acoustic bandpass filter circuit to block the signal in a stopband nonoverlapping with the passband.
